(19) United States
(12) Patent Application Publication
(10) Pub. No.: US 2009/0275479 A1
(43) Pub. Date: Nov. 5, 2009

(54) SUPERCONDUCTING OXIDE MATERIAL, PROCESS FOR PRODUCING THE SAME, AND SUPERCONDUCTING WIRE AND SUPERCONDUCTION APPARATUS BOTH EMPLOYING THE SUPERCONDUCTING MATERIAL

(75) Inventors: Jun-ichi Shimoyama, Tokyo (JP); Takeshi Kato, Osaka (JP); Koubei Yamazaki, Osaka (JP); Shin-ichi Kobayashi, Osaka (JP)

Correspondence Address: DRINKER BIDDLE & REATH (DC), 1500 K STREET, N.W., SUITE 1100, WASHINGTON, DC, 20005-1209, US

(73) Assignee: Sumitomo Electric Industries, Ltd., Osaka-shi (JP)

(21) Appl. No.: 12/282,447

(22) PCT Filed: Oct. 15, 2007
(86) PCT No.: PCT/JP2007/070073

§ 371 Date: Sep. 10, 2008

(30) Foreign Application Priority Data
Jan. 11, 2007 (JP) 2007-003362

(51) Int. Cl. H01B 12/00; H01L 39/24; H01L 39/00

(52) U.S. Cl. 505/230; 505/300; 505/121; 505/150; 174/125.1; 148/96; 423/594.7

(57) ABSTRACT

The invention offers a method of producing a (Bi, Pb)-2223-based oxide superconducting material. The method is for producing a (Bi, Pb)₂Sr₂Ca₂Cu₃O_{Z}-based oxide superconducting material. The method includes a material-mixing step for forming a mixed material and at least two heat treatment steps for heat-treating the mixed material. The at least two heat treatment steps has a first heat treatment step for forming (Bi, Pb)-2223 crystals and a second heat treatment step for increasing the Sr content of the (Bi, Pb)-2223 crystals after the (Bi, Pb)-2223 crystals are formed. The second heat treatment step is performed at a temperature lower than that employed in the first heat treatment step, so that the (Bi, Pb)-2223-based oxide superconducting material has a high critical temperature.

### TECHNICAL FIELD

The present invention relates to a (Bi, Pb)₂Sr₂Ca₂Cu₃O_{Z} (“z” is a number close to 10, and hereinafter referred to as (Bi, Pb) 2223)-based oxide superconducting material, the production method thereof, and a superconducting wire and a superconducting apparatus both incorporating the (Bi, Pb)-2223-based oxide superconducting material as their main phase.

### BACKGROUND ART

An oxide superconducting wire that has a (Bi, Pb)-2223 phase as a main constituent and that is produced by the metal sheath method is a useful wire, because it not only has a high critical temperature but also shows a high critical-current value even under a relatively simple cooling condition such as that produced by liquid nitrogen (see Nonpatent literature 1, for example). Nevertheless, when its performance is further improved, the range of its practical application will be further broadened. Therefore, it is desired that the performance of the (Bi, Pb)-2223-based superconducting material itself be improved as the main phase of the wire.

In addition, it is considered that by using the above-described (Bi, Pb)-2223-based superconducting wire, the energy loss can be significantly decreased in comparison with the case where a conventional normal-conduction conductor is used. Therefore, researchers and engineers have been concurrently developing a superconducting cable, a superconducting coil, a superconducting transformer, a superconducting magnetic energy storage (SMES), and other superconductivity-applied apparatuses all of which use the (Bi, Pb)-2223-based superconducting wire as the conductor.

A critical temperature (Tc) is one of the properties of the above-described superconducting material. When the critical temperature is raised, the temperature margin from the operating temperature can be increased. Consequently, when the above-described superconducting material is used for a superconducting wire, the rising of the critical temperature is reflected to the critical-current value (Ic). As a result, “Ic” is increased as well. As a technique for raising the critical temperature, a method is known in which for a (Bi, Pb)-2223-based superconducting material, a bulk-pellet material including grown (Bi, Pb)-2223 crystals is sealed under a vacuum condition to be heat-treated for about 100 hours at a temperature of nearly 700° C. (see Non-patent literature 2). The literature describes that this method raises the critical temperature from 110 K to 115 K.
Nonpatent literature 1: SEI Technical Review, March 2004, No. 164, pp. 36-42
Nonpatent literature 2: Jie Wang et al. “Enhancement of Tc in (Bi, Pb)-2223 superconductor by vacuum encapsulation and post-annealing” Physica C, Vol. 208, (1993), pp. 323-327

### DISCLOSURE OF THE INVENTION

### Problem to be Solved by the Invention

In the above-described technique, although the increase in Tc is achieved, merely the production parameters such as the composition of the starting material, the annealing temperature, and the annealing time are disclosed. No explanation is made with respect to the principle for the increasing of Tc. Consequently, when the condition such as the production apparatus is changed, it is difficult to achieve the maximum performance of Tc=115 K. Such a technique is not desirable in applying to the industrial production.

In view of the above-described circumstances, an object of the present invention is to offer not only a (Bi, Pb)-2223-based oxide superconducting material that achieves a high critical temperature with high reproducibility but also a superconducting wire and a superconducting apparatus both incorporating the superconducting material. For the (Bi, Pb)-2223-based oxide superconducting material, the present inventors have focused attention not only on the adjusting of the Sr content of the (Bi, Pb)-2223-based oxide superconducting material but also on the optimization of the adjusting condition. As a result, the present inventors have found a method of producing the above-described superconducting material that can achieve a high critical temperature with high reproducibility to complete the present invention.

### Means to Solve the Problem

The present invention offers a method of producing an oxide superconducting material. The method is for producing a (Bi, Pb)₂Sr₂Ca₂Cu₃O_{Z}-based oxide superconducting material. The method includes a material-mixing step for forming a mixed material and at least two heat treatment steps for heat-treating the mixed material. The at least two heat treatment steps has a first heat treatment step for forming (Bi, Pb)-2223 crystals and a second heat treatment step for increasing the Sr content of the (Bi, Pb)-2223 crystals after the (Bi, Pb)-2223 crystals are formed. The second heat treatment step is performed at a temperature lower than that employed in the first heat treatment step.

In the present invention, it is desirable that when the Sr content of the (Bi, Pb)-2223 crystals before the second heat treatment step is regarded as 1 to be used as a reference, the relative increment in the Sr content by the performing of the second heat treatment step be at least 0.02.

In the present invention, it is desirable that the first heat treatment step be performed by using a pressurized heat treatment.

In the present invention, it is desirable that the second heat treatment step be performed by using a pressurized heat treatment.

An oxide superconducting material of the present invention is produced by any of the above-described production methods. After the second heat treatment step, when its Cu content is used as a reference having a value of 3, the produced oxide superconducting material has an Sr content of at least 1.89 and at most 2.0 in relative terms.

Another oxide superconducting material of the present invention is also produced by any of the above-described production methods. After the second heat treatment step, the produced oxide superconducting material has (Bi, Pb)-2223 crystals whose unit cell has a c-axis length of at least 3.713 nm.

A superconducting wire of the present invention incorporates the oxide superconducting material produced by the above-described production method.

A superconducting apparatus of the present invention incorporates the above-described superconducting wire as a conductor.

### EFFECT OF THE INVENTION

According to the present invention, a (Bi, Pb)-2223-based oxide superconducting material having a high critical temperature can be produced with high reproducibility and high efficiency. A superconducting wire having a high critical temperature can be produced by incorporating the foregoing superconducting material. The use of the foregoing wire as the conductor enables the production of high performance superconducting apparatuses such as a superconducting cable, a superconducting coil, a superconducting transformer, and a superconducting magnetic energy storage (SMES).

### BRIEF DESCRIPTION OF THE DRAWING

FIG. 1 is a flow chart showing a production process of an oxide superconducting wire in an embodiment of the present invention.

FIG. 2 is a perspective view showing the internal structure of a superconducting cable as an example.

FIG. 3 is a schematic diagram showing an example of a typical superconducting magnet.

FIG. 4 is a schematic diagram showing an example of a typical superconducting transformer.

### EXPLANATION OF THE SIGN

21: Former
22: Conductor layer
23: Insulating layer
24: Magnetic-shield layer
25: Heat-insulating layer
26: Outer pipe
27: Oxide superconducting wire
31: Coil
32: Terminal
33: Persistent-current switch
41: Primary-side superconducting coil
42: Secondary-side superconducting coil
43: Primary-side terminal
44: Secondary-side terminal
45: Core

### BEST MODE FOR CARRYING OUT THE INVENTION

### Embodiment

Generally, the adjustment of the ratios of the cation constituents (Bi, Pb, Sr, Ca, and Cu) contained in a superconducting material is performed at the stage of the material mixing. For example, when ratios such as Bi:Pb:Sr:Ca:Cu=1.8:0.3:2.0:2.0:3.0 show the composition of the intended final superconducting phase, oxides or carbonates of the individual constituents are mixed with ratios close to the foregoing ratios. Then, heat treatments are repeated to obtain the final superconducting material having composition ratios close to the ratios of the starting materials.

In the above-described production method, it is sometimes difficult to obtain a (Bi, Pb)-2223 phase having the intended composition ratios. For example, in the case where the ratios Bi:Pb:Sr:Ca:Cu=1.8:0.3:2.0:2.0:3.0 are the composition ratios of the intended final composite, when a conventional process having a simple mixing and heat treatment is used, a phase lacking Sr will be mainly produced such as a superconducting phase having the ratios Bi:Pb:Sr:Ca:Cu=1.8:0.3:1.85:2.0-2.1:3.0, which are the ratios that permit the most stable existence. The remaining Sr will be precipitated in the form of nonsuperconducting compounds such as Sr—O, Sr—Ca—Pb—O. On the other hand, in view of the increase in Tc, it is recommended that the element ratios in a superconducting phase have ratios close to integer ratios such as (Bi, Pb):Sr:Ca:Cu=2:2:2:3.

In view of the above circumstances, the present inventors have found a production method as described below. First, a superconducting phase is formed with ratios that facilitate stable formation. Then, in that formed state, a specific atom is caused to form a solid solution with the superconducting phase. This technique produces a multicrystalline superconducting material composed of a large number of crystal grains having the intended composition ratios, which are close to integer ratios.

This technique is explained below more specifically. First, the starting materials are adjusted so as to have the ratios Bi:Pb:Sr:Ca:Cu=1.8:0.3:2.0:2.0:3.0. The starting materials are repeatedly subjected both to heat treatments at a temperature at which they sufficiently react with one another and to pulverizing processes. This operation produces a multicrystalline superconducting material formed of a nearly single (Bi, Pb)-2223 phase having the composition ratios Bi:Pb:Sr:Ca:Cu=1.8:0.3:1.85:2.0-2.1:3.0. The heat treatment performed in the above operation is referred to as a reaction heat treatment (a first heat treatment step). Subsequently, the superconducting material is heat-treated for at least 100 hours at a temperature not so high as to cause the formed individual (Bi, Pb)-2223 crystals to decompose, for example, at 600° C. to 750° C. This heat treatment causes Sr ions to form solid solutions with the (Bi, Pb)-2223 crystals. This heat treatment is referred to as a second heat treatment step.

When these operations are performed, while maintaining the crystal structure of the individual crystal grains of the (Bi, Pb)-2223 phase formed by the reaction heat treatment (the first heat treatment step), the Sr content of the individual crystal grains can be increased.

It is desirable that when the Sr content of the (Bi, Pb)-2223 crystals before the second heat treatment step is regarded as 1 to be used as a reference, the increment in the Sr content by the performing of the second heat treatment step be at least 0.02.

The above-specified increment in the Sr content is explained below. When the Sr content before the second heat treatment step is, for example, 1.85, this value is regarded as 1 to be used as a reference. In this case, when the Sr content becomes 1.92 by the performing of the second heat treatment step, the increment is calculated as (1.92/1.85−1)=0.038.

When the increment is less than 0.02, the increment is excessively small as the amount of variation in the composition. In other words, the difference from the content before the second heat treatment step is small, so that it is unlikely to achieve a remarkable effect. On the other hand, the upper limit of the increment cannot be specified. Nevertheless, the increment by which the Sr content becomes 2.0 (integer composition ratio) is the increment at which Tc becomes the highest.

Furthermore, the present inventors have also found that it is effective to perform the first and second heat treatment steps by using a pressurized heat treatment.

The reason is explained below. In the case where Sr ions are caused to form solid solutions with the (Bi, Pb)-2223 crystals, when Sr compounds, which form a nonsuperconducting phase, are in intimate contact with the (Bi, Pb)-2223 crystals, the diffusion of the Sr ions (for example, the diffusion from the nonsuperconducting crystals to the superconducting crystals or the diffusion between the superconducting crystals) occur smoothly. Therefore, it is desirable that the individual crystals in the superconductor be bonded with one another with the largest possible strength. To form and maintain such a condition, a pressurized heat treatment is used, which increases the degree of intimate contact between the crystals.

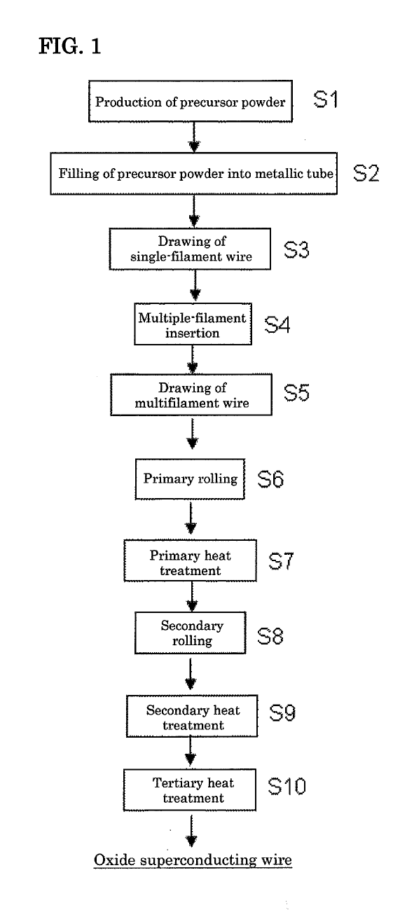

FIG. 1 is a chart showing an example of a production process of a superconducting wire incorporating a superconducting material of the present invention. With reference to FIG. 1, a concrete process of the present invention is explained below.

First, material powders (Bi₂O₃, PbO, SrCO³, CaCO₃, and CuO) are mixed with intended ratios. The mixed powder is subjected to repeated heat treatments and pulverizations to produce a precursor powder (Step S1). The precursor powder is filled into a metallic tube (Step S2). The precursor includes, for example, a (Bi, Pb)₂Sr₂Ca₁Cu₂O_{±δ} phase (δ is a number close to 0.1, and hereinafter referred to as a (Bi, Pb)-2212 phase), a Bi₂Sr₂Ca₁Cu₂O_{8±δ} phase (δ is a number close to 0.1, and hereinafter referred to as a Bi-2212 phase), a (Bi, Pb)-2223 phase, and so on. It is desirable that the metallic tube be formed by using silver or a silver alloy, which are unlikely to form a compound with the precursor.

The above-described metallic tube is processed by drawing until it comes to have an intended diameter. Thus, a single-filament wire is produced in which the precursor as the core member is covered with a metal such as silver (Step S3). A multitude of single-filament wires described above are bundled together to be inserted, without clearance, into a metallic tube made of, for example, silver (multiple-filament insertion; Step S4). This operation produces a multifilament structural body that has a large number of core members formed of the material powder.

The multifilament structural body is processed by drawing until it comes to have an intended diameter. This operation produces an isotropic multifilament wire, having a circular or polygonal cross-sectional shape, in which the material powders are embedded in a sheath portion made of, for example, silver (Step S5). Thus, an isotropic multifilament wire is obtained that has a configuration in which the material powders of the oxide superconducting wire are covered with a metal. Subsequently, the isotropic multifilament wire is rolled (a primary rolling; Step S6). This operation produces a tape-shaped oxide superconducting wire.

Next, the tape-shaped wire is heat-treated (a primary heat treatment; Step S7). This heat treatment is performed, for example, at a temperature of about 800° C. to 850° C. in an atmosphere having an oxygen partial pressure of 1 to 20 kPa. This heat treatment forms an intended oxide superconducting phase from the material powder. This heat treatment transforms the precursor into an intended (Bi, Pb)-2223 crystal.

Subsequently, the wire is rolled again (a secondary rolling; Step S8). The performing of the second rolling removes voids formed by the primary heat treatment. Then, the wire is heat-treated, for example, at a temperature of about 820° C. to 840° C. in an atmosphere having an oxygen partial pressure of 1 to 20 kPa (a secondary heat treatment; Step S9). At this moment, it is desirable that the heat treatment be performed in a pressurized atmosphere. This heat treatment not only transforms a portion remaining without being reacted in Step S7 into the (Bi, Pb)-2223 phase but also strongly bonds an individual (Bi, Pb)-2223 crystal with another (Bi, Pb)-2223 crystal or with a nonsuperconducting phase. Steps S7 and S9 constitute the first heat treatment step.

Finally, the wire after the secondary heat treatment is heat-treated again at a temperature of about 600° C. to 750° C. in an atmosphere having a total pressure between atmospheric pressure and 50 MPa and an oxygen partial pressure of 1 to 30 kPa (a tertiary heat treatment; Step S10). This heat treatment causes Sr ions to form solid solutions with the (Bi, Pb)-2223 crystals, increasing the Sr content of the (Bi, Pb)-2223 crystals. Step S10 constitutes the second heat treatment step.

A superconducting wire produced through a method of the present invention has a high critical temperature. Consequently, the wire can increase the temperature margin from the operating temperature at the time of the liquid-nitrogen cooling. In addition, because the wire has strong bonding between the crystal grains, the wire can achieve a high critical-current value.

Moreover, a superconducting apparatus of the present invention has excellent superconducting properties, because it incorporates a superconducting wire having a high critical temperature and a high critical-current value. In the above description, the superconducting apparatus has no particular limitation provided that it incorporates the above-described superconducting wire. The types of superconducting apparatus include a superconducting cable, a superconducting coil, a superconducting magnet, a superconducting transformer, and a superconducting magnetic energy storage (SMES). For example, in a superconducting cable for AC use and a superconducting transformer, the increase in the critical-current value decreases the loss at the operating current. On the other hand, in apparatuses mainly used for DC applications, such as a superconducting magnet and a superconducting magnetic energy storage (SMES), the maximum generating magnetic field and the maximum storing energy are increased significantly.

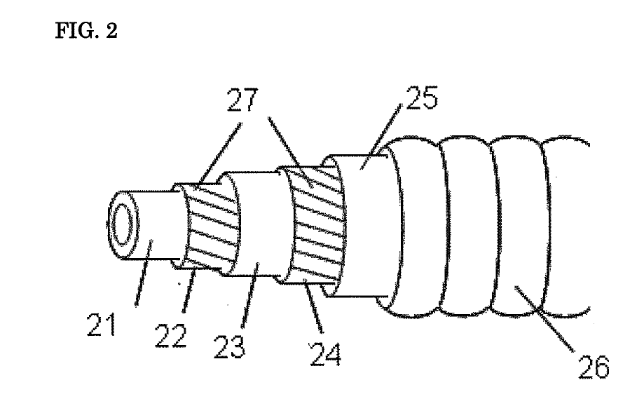

FIG. 2 is a perspective view showing the internal structure of a superconducting cable as an example. Oxide superconducting wires 27 of the present invention are helically laid over a former 21 to form a conductor layer 22. An insulating layer 23 is provided on the conductor layer 22. Oxide superconducting wires 27 are helically laid over the insulating layer 23 to form a magnetic-shield layer 24. They are covered with a heat-insulating layer 25 and housed in an outer pipe 26.

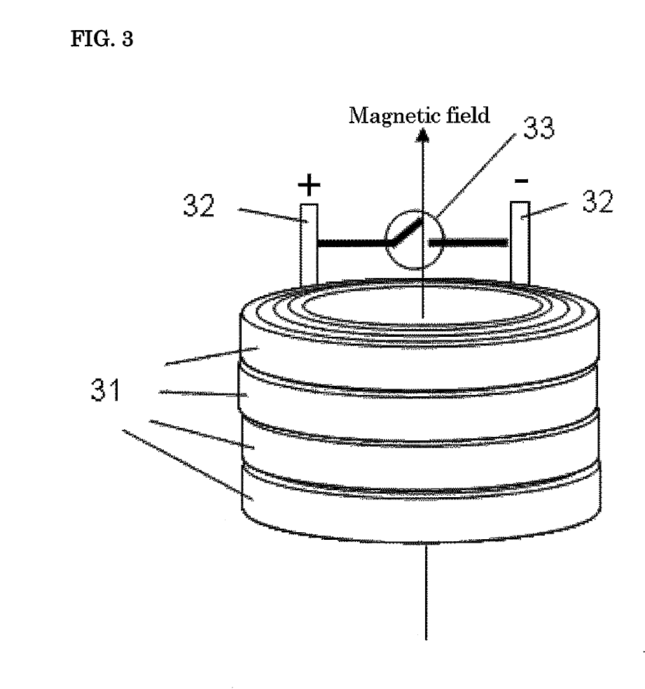

FIG. 3 is a schematic diagram showing an example of a typical superconducting magnet. An oxide superconducting wire of the present invention is wound in the shape of a pancake to form a coil 31. A plurality of coils 31 described above are electrically connected according to the purpose. When an electric current is supplied to them from terminals 32, a magnetic field is generated inside the coils 31. A persistent-current switch 33 made with oxide superconducting wires is connected to both terminals 32. After the coils 31 are excited to generate an intended magnetic field, when the persistent-current switch 33 is closed, a persistent current flows in a loop formed of the coils 31 and the persistent-current switch 33. This current flows with almost no attenuation, so that the energy can be stored as a magnetic field. When required, the persistent-current switch 33 is opened so that a current flows to the terminals 32. Thus, a current can be taken to the outside. When used as described above, the apparatus can be used as a superconducting magnetic energy storage (SMES).

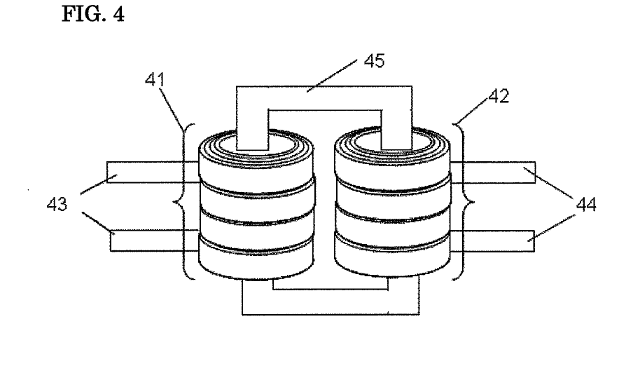

FIG. 4 is a schematic diagram showing an example of a typical superconducting transformer. A primary-side superconducting coil 41 is magnetically coupled with a secondary-side superconducting coil 42 through a core 45 made of, for example, iron. The primary-side superconducting coil 41 is fed with an AC current from primary-side terminals 43. The AC current generates an alternating magnetic field in the primary-side superconducting coil 41. Another alternating magnetic field is induced in the secondary-side superconducting coil 42 through the core 45. The induced alternating magnetic field generates an AC voltage in the secondary-side superconducting coil 42 through an induction phenomenon. The generated voltage is taken across secondary-side terminals 44. When the secondary-side superconducting coil 42 has a different number of turns from that of the primary-side superconducting coil 41, the secondary side can generate a different voltage from that of the primary side.

### Example

Based on an example, the present invention is explained more specifically in the following.

### Example

Material powders (Bi₂O₃, PbO, SrCO₃, CaCO₃, and CuO) were mixed with the ratios Bi:Pb:Sr:Ca:Cu=1.8:0.3:2.0:2.0:3.0. The mixed powder was subjected to a treatment, in the atmosphere, composed of the heating for eight hours at 700° C., the pulverizing, the heating for 10 hours at 800° C., the pulverizing, the heating for four hours at 840° C., and the pulverizing to obtain a precursor powder. Alternatively, the precursor powder can also be produced by using the multifilament structural body as described below. A nitric acid solution that dissolves the five types of material powders is sprayed into a heated furnace to evaporate water in the droplets of the metallic nitrate solution. Subsequently, the pyrolysis of the nitrate and the reaction between and synthesis of metallic oxides occur instantaneously to form the precursor powder. The precursor powder produced through the foregoing method is a powder mainly formed of a (Bi, Pb)-2212 phase or a Bi-2212 phase.

The precursor powder produced as described above was filled into a silver tube having an outer diameter of 25 mm and an inner diameter of 22 mm. The silver tube was drawn until it comes to have a diameter of 2.4 mm to produce a single-filament wire. Fifty-five single-filament wires described above were bundled together to be inserted into a silver tube having an outer diameter of 25 mm and an inner diameter of 22 mm. The silver tube was drawn until it comes to have a diameter of 1.5 mm to obtain a multifilament wire having 55 filaments. The multifilament wire was processed by rolling to obtain a tape-shaped wire having a thickness of 0.25 mm. The obtained tape-shaped wire underwent a primary heat treatment that treated the wire at 820° C. to 840° C. for 30 to 50 hours in an 8-kPa oxygen atmosphere.

The tape-shaped wire after the primary heat treatment was rolled again so as to attain a thickness of 0.23 mm. The tape-shaped wire rolled again was subjected to a secondary heat treatment that treated the wire at 820° C. to 840° C. for 50 to 100 hours in a pressurized atmosphere having a total pressure of 30 MPa including an oxygen partial pressure of 8 kPa. A part of the obtained wire was cut (Sample No. 1, which is Comparative example) to perform the following evaluation: measurement of the critical temperature, measurement of the critical-current value, compositional analysis, and structural analysis.

The remaining portion was heat-treated again (a tertiary heat treatment; Step S10) under the following various conditions (Sample No. 2, which is Comparative example; Sample Nos. 3 to 11, which are Examples):
Atmosphere: an atmosphere at atmospheric pressure (0.1 MPa) or a pressurized atmosphere at 30 MPa
Temperature: 400° C. to 725° C.
Duration of time: 100 to 1,000 hour
Oxygen partial pressure: 1 or 21 kPa.

The conditions for the heat treatment are shown in Table I. These samples were also subjected to the same evaluation as that described above.

The evaluation was performed as described below. The critical temperature (Tc) was measured and defined as shown below. While the temperature of the obtained superconducting wires was being raised from the liquid nitrogen temperature, the susceptibility of the wires was measured by using a superconducting quantum interference device (SQUID)-type flux meter (MPMS-XL5S made by Quantum Design Co. Ltd.). The susceptibility at various temperatures was measured by applying a magnetic field of 0.2 Oe (15.8 A/m) in a direction perpendicular to the tape surface of the superconducting wire. The magnetic susceptibility at various temperatures was normalized by using the magnetic susceptibility at 95 K. The temperature at which the magnitude of the normalized magnetic susceptibility became −0.001 was defined as the critical temperature.

The critical-current value was measured and defined as shown below. First, a current-voltage curve was obtained through the measurement using the four-terminal method at a temperature of 77 K and in a zero magnetic field. By using the curve, the value of the current required to generate a voltage of 1×10⁻⁶ V per cm of the wire was obtained and defined as the critical-current value.

The structural analysis was conducted using the powder X-ray diffraction. Then, the constituent phases were evaluated, and the c-axis length of the unit cell of the (Bi, Pb)-2223 crystals was calculated. The compositional analysis was performed using the energy dispersive X-ray (EDX) method. The composition was calculated as follows. For each specimen, compositions at five locations were analyzed. Their average value was used as the composition ratio of each specimen.

The obtained evaluation results for the above-described properties are shown in Table I.

TABLE I

| | Condition of tertiary heat treatment | | | | | | | | | |
|---|---|---|---|---|---|---|---|---|---|---|
| | | | | Oxygen | | | | | | |
| | | | Total | partial | Critical | Critical- | C-axis | | Increment | |
| Sample | Temperature | Time | pressure | pressure | temperature | current value | length | Sr | in Sr | |
| No. | (° C.) | (h) | (MPa) | (kPa) | (K) | (A) | (nm) | content | content | |
| 1 | No tertiary heat treatment was performed. | | | | 110.2 | 110 | 3.709 | 1.85 | — | Comparative |
| | | | | | | | | | | example |
| 2 | 400 | 100 | 0.1 | 21 | 110 | 109 | 3.708 | 1.85 | 0.000 | Comparative |
| | | | | | | | | | | example |
| 3 | 655 | 100 | 0.1 | 21 | 114.5 | 126 | 3.715 | 1.91 | 0.032 | Example |
| 4 | 700 | 100 | 0.1 | 21 | 114.8 | 130 | 3.713 | 1.89 | 0.022 | Example |
| 5 | 725 | 100 | 0.1 | 21 | 114.2 | 125 | 3.713 | 1.89 | 0.022 | Example |
| 6 | 675 | 500 | 0.1 | 21 | 115.3 | 128 | 3.716 | 1.92 | 0.038 | Example |
| 7 | 675 | 1,000 | 0.1 | 21 | 116 | 118 | 3.718 | 1.94 | 0.049 | Example |
| 8 | 720 | 100 | 0.1 | 1 | 114.1 | 151 | 3.713 | 1.90 | 0.027 | Example |
| 9 | 720 | 200 | 0.1 | 1 | 114.3 | 153 | 3.715 | 1.92 | 0.038 | Example |
| 10 | 720 | 100 | 30 | 1 | 114.5 | 162 | 3.714 | 1.92 | 0.038 | Example |
| 11 | 720 | 200 | 30 | 1 | 114.8 | 165 | 3.715 | 1.94 | 0.049 | Example |

Sample No. 1 (Comparative example) has terminated its production process after finishing the secondary heat treatment. In other words, it has not undergone the heat treatment (the tertiary heat treatment) of the present invention for increasing the Sr content. Sample No. 2 (Comparative example) shows no increase in its Sr content from that of Sample No. 1, although it has undergone the tertiary heat treatment. An explanation is given below by comparing Sample Nos. 1 and 2 with Sample Nos. 3 to 11 (Examples), which have undergone the tertiary heat treatment and which show an increase in Sr content by undergoing the treatment.

Sample No. 1, which has not undergone the Sr content-increasing heat treatment (the tertiary heat treatment), has a critical temperature of 110.2 K and a critical-current value of 110 A. By using the analyzed result, the copper (Cu) content is regarded as 3, and the Sr content is obtained by calculating the ratio to the Cu content of 3. According to the foregoing method, the Sr content (the composition ratio) becomes 1.85.

Sample Nos. 3 to 11, which have undergone the tertiary heat treatment, improve both in critical temperature and in critical-current value in comparison with Sample No. 1. On the other hand, Sample No. 2 shows no improvement in both properties, in spite of the fact that it has also undergone the tertiary heat treatment. The reason is that although it has undergone the tertiary heat treatment, its condition is not sufficient and this insufficient condition has not caused an increase in the Sr content by the formation of solid solutions of Sr ions with the (Bi, Pb)-2223 crystals.

Next, the Sr content of Sample Nos. 3 to 11, which are Examples, is obtained by calculating the ratio to the copper (Cu) content that is used as a reference having a value of 3. The calculated results are 1.89 or more. Therefore, it can be said that it is desirable to have an Sr content of at least 1.89. In addition, Table I shows that as the critical temperature rises, the c-axis length of the unit cell has a tendency to increase. It is also found that it is desirable that the c-axis length be at least 3.713 nm.

It is to be considered that the above-disclosed embodiments and examples are illustrative and not restrictive in all respects. The scope of the present invention is shown by the scope of the appended claims, not by the above-described explanations. Accordingly, the present invention is intended to cover all revisions and modifications included within the meaning and scope equivalent to the scope of the claims.

1. A method of producing an oxide superconducting material, the method being for producing a (Bi, Pb)₂Sr₂Ca₂Cu₃O_{Z}-based oxide superconducting material; the method comprising:
(a) a material-mixing step for forming a mixed material; and
(b) at least two heat treatment steps for heat-treating the mixed material; in which method, the at least two heat treatment steps comprise:
(c) a first heat treatment step for forming (Bi, Pb)-2223 crystals; and
(d) a second heat treatment step for increasing the Sr content of the (Bi, Pb)-2223 crystals after the (Bi, Pb)-2223 crystals are formed;
the second heat treatment step being performed at a temperature lower than that employed in the first heat treatment step.

2. The method of producing an oxide superconducting material as defined by claim 1, wherein when the Sr content of the (Bi, Pb)-2223 crystals before the second heat treatment step is regarded as 1 to be used as a reference, the increment in the Sr content by the performing of the second heat treatment step is at least 0.02.

3. The method of producing an oxide superconducting material as defined by claim 1, wherein the first heat treatment step is performed by using a pressurized heat treatment.

4. The method of producing an oxide superconducting material as defined by claim 2, wherein the first heat treatment step is performed by using a pressurized heat treatment.

5. An oxide superconducting material produced by the method of producing an oxide superconducting material as defined by claim 1, the produced oxide superconducting material having an Sr content of at least 1.89 and at most 2.0 after the second heat treatment step when its Cu content is used as a reference having a value of 3.

6. An oxide superconducting material produced by the method of producing an oxide superconducting material as defined by claim 1, the produced oxide superconducting material having (Bi, Pb)-2223 crystals whose unit cell has a c-axis length of at least 3.713 nm after the second heat treatment step.

7. A superconducting wire incorporating the oxide superconducting material produced by the method of producing an oxide superconducting material as defined by claim 1.

8. A superconducting apparatus incorporating, as a conductor, the superconducting wire as defined by claim 7.

9. The method of producing an oxide superconducting material as defined by claim 1, wherein the second heat treatment step is performed by using a pressurized heat treatment.

10. The method of producing an oxide superconducting material as defined by claim 2, wherein the second heat treatment step is performed by using a pressurized heat treatment.

11. The method of producing an oxide superconducting material as defined by claim 3, wherein the second heat treatment step is performed by using a pressurized heat treatment.

12. The method of producing an oxide superconducting material as defined by claim 4, wherein the second heat treatment step is performed by using a pressurized heat treatment.
